(19) United States
(12) Patent Application Publication
(10) Pub. No.: US 2001/0026950 A1
(43) Pub. Date: Oct. 4, 2001

(54) Method of manufacturing a nitrogen-based semiconductor substrate and a semiconductor element by using the same

(75) Inventors: Haruo Sunakawa, Tokyo (JP); Akira Usui, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 09/821,411

(22) Filed: Mar. 29, 2001

(30) Foreign Application Priority Data
Mar. 29, 2000 (JP) 91963/2000

(51) Int. Cl. H01L 21/00

(52) U.S. Cl. 438/47; 438/967

(57) ABSTRACT

In a method of manufacturing a semiconductor device by using a sapphire substrate, a nitrogen-based semiconductor thick film is deposited on the sapphire substrate by VPE and is left without any cracks by etching the sapphire substrate by an etchant. The nitrogen-based semiconductor thick film serves as a substrate for manufacturing the semiconductor device.

### BACKGROUND OF THE INVENTION

This invention relates to a method of manufacturing a nitrogen-based semiconductor layer which serves as a nitrogen-based semiconductor substrate used for manufacturing a semiconductor laser, a light emitting diode, or the like.

Conventionally, it is known that, among such nitrogen-based semiconductors, gallium nitride (GaN) is of a direct transition type and has a wide forbidden band- width, such as 3.4 eV. In this connection, the nitride has been often used as a material of a blue color light emitting device.

Herein, such a light emitting device is manufactured by the use of an epitaxial growth technique. In this connection, it is preferable that a substrate is formed by a substance of a bulk crystal that is the same as an epitaxial layer.

However, it is very difficult to manufacture a bulk crystal of GaN because a dissociation pressure of nitrogen is high in a crystal of the GaN. In other words, a single crystal substrate of GaN can not be obtained, which makes it difficult to manufacture an device structure by executing epitaxial growth on the single crystal substrate of GaN.

Under the circumstances, a light emitting device structure is manufactured by preparing a substrate, such as sapphire (Al₂O₃), silicon (Si), silicon carbide (SiC), zinc oxide (ZnO) which may be called a hetero-substrate and by epitaxially growing a nitrogen-based semiconductor on the substrate. Practically, the hetero-substrate is different from the nitrogen-based semiconductor in physical properties and chemical properties, such as a lattice constant, a thermal expansion coefficient.

Herein, it is assumed that a semiconductor laser is manufactured as the light emitting device by using the above-mentioned technique, In general, the semiconductor laser has a cavity formed by a pair of mirrors opposite to and distant from each other. Such mirrors are provided by cleavage planes over a substrate and a laser device structure on the assumption that the cleavage planes are identical with each other on the substrate and the laser device structure.

However, the cleavage plane of the epitaxial growth layer is usually different from that of the hetero-substrate. For example, let the sapphire be used as the hetero-substrate of the nitrogen-based semiconductor laser. In this event, the cleavage plane of the epitaxial layer is given by a (1 −100) plane (M plane) and is practically different from the cleavage plane (M plane) of the sapphire by 30° . This practically makes it difficult to form the mirror surfaces for the cavity by the use of a cleavage technique.

Therefore, reactive ion etching (RIE) should be inevitably executed so as to form the mirror surfaces of the cavity in the nitrogen-based semiconductor structure on the hetero-substrate. However, it is difficult to obtain the cavity surfaces of an excellent flatness by forming the mirror surfaces of the cavity by using the reactive ion etching.

In addition, a semiconductor laser device usually has contact electrodes formed on a surface of an epitaxial growth layer and a back surface of a substrate. In the nitrogen-based semiconductor laser device that has a non-conductive substrate, any contact electrode can not be formed on a back surface of a non-conductive substrate, such as sapphire substrate. In order to form the contact electrode, reactive ion etching should be conducted like formation of the mirror surfaces until a contact layer deposited on the non-conductive substrate is exposed.

Herein, consideration may be made about attaching a contact electrode to a back surface of the nitrogen-based semiconductor layer by removing the hetero-substrate. It is to be noted that a nitrogen-based substrate (for example, GaN) should be deposited to a thickness of about 50 μm or more in order to sufficiently withstand a polishing process and any other processes. However, attention should be directed to a large difference of the thermal expansion coefficients between the sapphire and the nitrogen-based semiconductor substrate. For example, the nitrogen-based semiconductor substrate (GaN) and the sapphire have the thermal expansion coefficients of 5.59×10⁻⁶/K and 7.5×10⁻⁶/K along a c-axis and an a-axis, respectively. When the grown GaN layer is cooled to a room temperature, a warp or bend of a convex shape appears on the GaN layer. This is similar when a nitrogen-based semiconductor device structure is grown on the sapphire. At any rate, the sapphire also warps bend along with the GaN layer or the nitrogen-based semiconductor device structure.

Herein, it is pointed out that uniformly polishing the warped sapphire encounters a difficulty. In addition, it happens that cracks tend to take place in the nitrogen-based semiconductor layer and semiconductor device structure grown on the sapphire. This is because the sapphire becomes thin during the polishing and, as a result, a radius curvature for the warp of the sapphire is varied with time.

### SUMMARY OF THE INVENTION

It is an object of this invention to provide a method of leaving a nitrogen-based semiconductor layer as a nitrogen-based substrate which serves to deposit an epitaxial layer thereon to manufacture a nitrogen-based semiconductor device structure.

It is another object of this invention to provide a method of the type described, which is helpful to remove a hetero-substrate from the nitrogen-based semiconductor layer without any influence to the nitrogen-based semiconductor layer.

It is still another object of this invention to provide a method of manufacturing a nitrogen-based semiconductor device by using the nitrogen-based semiconductor substrate left in the above-mentioned method.

According to this invention, a method is for use in manufacturing a nitrogen-based semiconductor layer. The method comprises the steps of growing the nitrogen-based semiconductor layer on a fundamental or provisional substrate which forms a hetero-junction with the nitrogen-based semiconductor layer and etching out the provisional substrate by the use of an etchant for the provisional substrate to leave only the nitrogen-based semiconductor layer as a nitrogen-based semiconductor substrate. The method may further comprises, before the etching step, the step of covering the nitrogen-based semiconductor layer with a protection layer against the etchant. In this event, the etching step is carried out with the nitrogen-based semiconductor layer covered with the protection layer to etch out the provisional substrate and to thereby leave the nitrogen-based semiconductor layer and the protection layer.

The nitrogen-based semiconductor layer may be shaped into a nitrogen-based semiconductor device structure to form a nitrogen-based semiconductor device.

Alternatively, the method further may comprise the step of processing the nitrogen-based semiconductor substrate into a nitrogen-based semiconductor device after the provisional substrate is etched out.

At any rate, the provisional substrate may be, for example, a sapphire substrate while the etchant may be formed by a mixed solution of phosphoric acid and sulfuric acid or another mixed solution including the phosphoric acid and the sulfuric acid. In addition, the protection layer is formed by at least one material selected from a group consisting of Au, Pt, Ti—Au, Pd—Au, Ni—Au, Ti—Pt—Au, AuZn, and AuGe.

Moreover, the nitrogen-based semiconductor layer may include either InₓGa₁₋ₓN (0≦x≦1) or AlₓGa₁₋ₓN (0≦x≦1). Alternatively, the nitrogen-based semiconductor layer includes at least two components selected from a group consisting of InₓGa₁₋ₓN (0≦x≦1), AlₓGa₁₋ₓN (0≦x≦1), and AlₓIn_{y}Ga_{1-x-y}N (0≦x+y≦1).

### BRIEF DESCRIPTION OF THE DRAWING

FIG. 1 is a sectional view of a conventional nitrogen-based semiconductor laser device;

FIGS. 2A, 2B, 2C, and 2D show a schematic views for use in describing successive processes of a method according to a first embodiment of this invention;

FIG. 3 shows a graph for use in describing a relationship between an etching rate and a ratio of sulfuric acid/phosphoric acid included in an etchant;

FIG. 4 shows a graphical representation for use in describing a relationship between an etching temperature and an etching rate;

FIGS. 5A, 5B, and 5C show schematic views for use in describing successive processes of a method according to a second embodiment of this invention;

FIGS. 6A, 6B, and 6C show similar views for use in describing a method according to a third embodiment of this invention.

### DESCRIPTION OF THE PREFERRED EMBODIMENTS

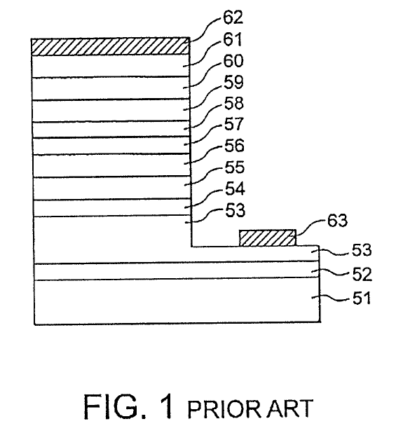

Referring to FIG. 1, description will be at first directed to a conventional nitrogen-based semiconductor laser device which is manufactured by a metalorganic vapor phase epitaxy (MOPVE) method and which is substantially equivalent to that referenced by the preamble of the instant specification. Specifically, provision is made of a sapphire substrate 51 which has a surface of (0001) plane and which serves as a provisional substrate. On the surface of the sapphire substrate 51, an undoped nitrogen gallium (GaN) is deposited as a buffer layer 52 to a thickness of 30 nm at a low temperature. Next, successively deposited on the buffer layer 52 are an n-type GaN contact layer 53 of 3 μm thick doped with Si, an n-type In_{0.2}Ga_{0.8}N layer 54 of 1 μm thick doped with Si, an n-type Al_{0.15}Ga_{0.85}N clad layer 55 of 0.4 μm thick doped with Si, and an n-type GaN optical guide layer 56 of 0.1 μm thick doped with Si. Furthermore, successively deposited on the n-type GaN optical guide layer 56 is an active layer 57 of a multi-quantum well structure that has a period of three and that is composed of an undoped In_{0.2}Ga_{0.8}N quantum well layer of 2.5 nm thick and an undoped In_{0.05}Ga_{0.95}N barrier layer. On the active layer 57, deposition is successively made of a p-type Al_{0.2}Ga_{0.8}N layer 58 of 20 nm thick doped with Mg, a p-type GaN guide layer 59 of 0.1 μm thick doped with Mg, a p-type Al_{0.15}Ga_{0.85}N clad layer 60 of 0.4 μm doped with Mg, and a p-type GaN contact layer 61 of 0.5 μm thick doped with Mg.

On the p-type GaN contact layer 61 and the n-type GaN contact layer 53, are deposited a p-type electrode 62 of Ni—Au and an n-type electrode 63 of Ti—Al, respectively.

The conventional nitrogen-based semiconductor laser device or device illustrated in FIG. 1 has shortcomings as mentioned in the preamble of the instant specification.

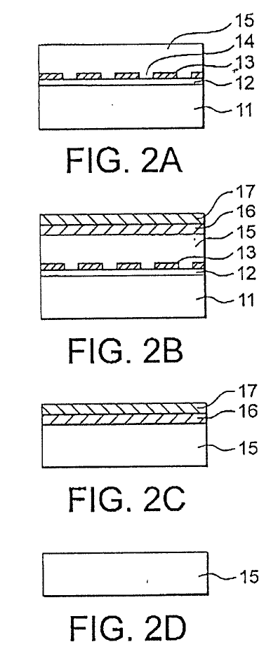

Referring to FIGS. 2A to 2D, description will be made about a method according to an embodiment of this invention. In the illustrated example, it is assumed that a sapphire substrate 11 is used as a provisional substrate to deposit or epitaxially grow a nitrogen-based semiconductor layer and to provide a heterostructure between the sapphire substrate 11 and the nitrogen-based semiconductor layer. In this connection, the sapphire substrate 11 may be referred to as a hetero-substrate.

In addition, the sapphire substrate 11 is finally removed from the nitrogen-based semiconductor layer by the use of an etchant, namely, an etching solution, as will become clear later in detail. As an etchant for etching a sapphire, L. A. Marasina et al have reported, in Crystal Res.& Technol. 17, 1982. 3, pages 365 to 371, a mixed solution or liquid of phosphoric acid (86%) and sulfuric acid (95%) that is heated. According to this report, description has been directed to an etching rate of the mixed solution mentioned above but no consideration has been made at all about an influence of the mixed solution on any other material deposited on the sapphire.

From this report, it is difficult to consider or anticipate an influence of the mixed solution on a nitrogen-based semiconductor layer (for example, GaN) epitaxially grown on a sapphire substrate.

Under the circumstances, the inventors' experimental studies have been focused on an etchant which can dissolve a sapphire substrate. As a result, a mixed solution of phosphoric acid and sulfuric acid has been selected as the etchant like in the above-mentioned report and has been raised to a temperature of 300° C. However, it has been found out that the above-mentioned etchant kept at the temperature of 300° C. has an etching rate that is as low as about 10 μm/hour and takes more than ten hours so as to etch out and remove the sapphire substrate of 300 μm thick.

Furthermore, the inventors' experiments have been made in a similar manner so as to investigate an influence of the mixed solution on a GaN layer selected as a nitrogen-based semiconductor layer. In consequence, it has been found out that the GaN layer is etched at an etching rate not lower than 10 μm/hour by the mixed solution kept at a temperature of 300° C. or more.

Subsequently, the researches have been done in a relationship between a ratio of phosphoric acid to sulfuric acid in the mixed solution and an etching rate (μm/hour) of the sapphire substrate. To this end, etching experiments of the sapphire substrate have been conducted by varying a content of sulfuric acid to a content of phosphoric acid in the mixed solution, with a temperature kept unchanged.

The sapphire substrate has been previously measured in thickness before the etching experiments and has been thereafter etched for a predetermined time by the use of the mixed solution of phosphoric acid and sulfuric acid. After the etching, a difference of thickness has been measured between the sapphire substrate prior to the etching and the etched sapphire substrate and the etching rate (μm/hour) has been calculated from the difference of thickness. In this event, the temperature of the etchant has been kept at a temperature of 335° C. while the ratio of sulfuric acid to phosphoric acid in the etchant has been varied within a range of 1:0.5 to 3. A beaker with a reflux condenser has been used during the etching so as to prevent amounts of phosphoric acid and sulfuric acid from being reduced due to vaporization and to avoid a variation of concentration. Moreover, moisture content has been thoroughly vaporized from the mixed solution of phosphoric acid and sulfuric acid and thereafter the etching has been conducted.

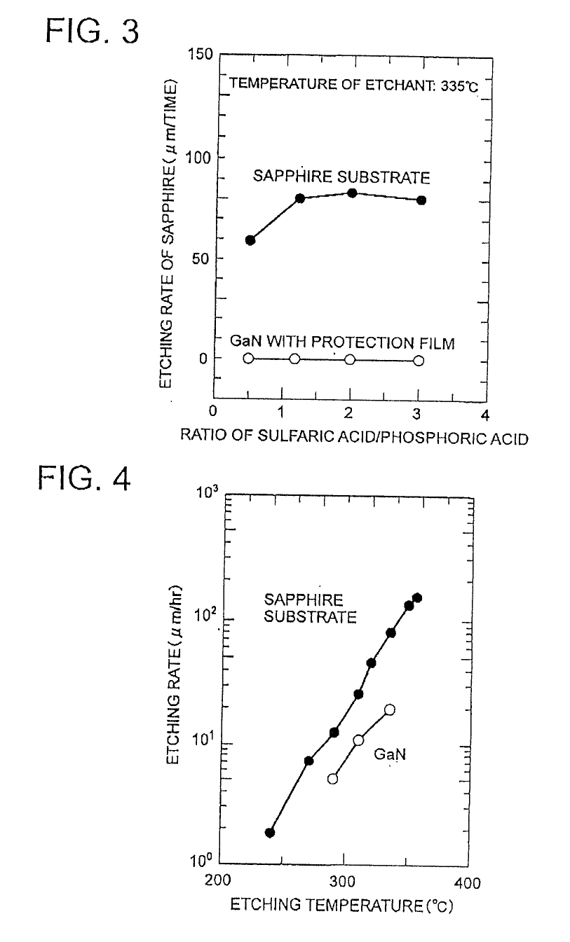

Temporarily referring to FIG. 3, illustration is made of a relationship between the etching rate and the ratio of sulfuric acid to the phosphoric acid both of which are taken along the ordinate and the abscissa of FIG. 3, respectively. As illustrated in FIG. 3, the solution or etchant is kept at the temperature of 335° C. while the ratio of sulfuric acid to phosphoric acid is varied within a range between 1 and 3. In consequence, the sapphire substrate is etched at the etching rate of about 80 μm/hour.

In addition, it has been confirmed according to the experiments that the mixed solution can be stably kept at a desired temperature by removing the moisture content from the mixed solution, which makes it possible to etch the sapphire substrate at a constant etching rate and to thus make an etching amount proportional to an etching time, Next, the other experiments have been conducted about a variation of the etching rates of the sapphire substrate and the nitrogen-based semiconductor by varying a temperature of the mixed solution of the phosphoric acid and the sulfuric acid. Specifically, the ratio of the phosphoric acid and the sulfuric acid in the mixed solution was kept at 1:2 and the temperature of the mixed solution was varied within a range between 240° C. and 360° C. In the experiments, use was made of the sapphire substrates on which GaN was epitaxially grown.

Referring to FIG. 4, illustrated is a relationship between a temperature (namely, etching temperature) of a mixed solution and etching rates of GaN and a sapphire substrate both of which are taken along the abscissa and the ordinate of FIG. 4, respectively. As shown in FIG. 4, each etching rate of GaN and the sapphire substrate is increased as the etching temperature of the mixed solution rises up. In addition, the etching rate of GaN is slow in comparison with that of the sapphire substrate. Accordingly, it has been found out in connection with the sapphire substrate with the nitrogen-based semiconductor layer or semiconductor device structure that only the sapphire substrate can be removed with the GaN left un-etched, by using a difference of the etching rates between GaN and the sapphire substrate.

Herein, it is to be noted that the mixed solution etches not only the sapphire substrate but also the GaN layer, as shown in FIG. 4. Consequently, it has been observed that a surface of the GaN layer is roughened unevenly. Taking this into consideration, it is preferable that a protection film is deposited on the surface of the nitrogen-based semiconductor layer so as to protect its surface being roughened.

Deposition of the protection film on the nitrogen-based semiconductor surface makes it possible to shorten an etching time of the sapphire substrate even when the etching rate is raised up by increasing the etching temperature. This is because the nitrogen-based semiconductor is not adversely affected by the mixed solution. In other words, it is possible to widen the difference of the etching rates between the sapphire substrate and the GaN layer by covering the GaN layer with the protection film.

Herein, the protection film deposited on the nitrogen-based semiconductor surface may preferably have an etching resistance property and more preferably may not adversely affect the nitrogen-based semiconductor during deposition and removal of the protection film.

Now, description will be made about a first embodiment of this invention.

[First Embodiment]

Referring back to FIGS. 2A through 2D, description will be made about a method according to a first embodiment of this invention. In this method, a nitrogen-based semiconductor substrate is formed by providing a structure composed of a sapphire substrate and a nitrogen-based semiconductor thick film grown on the sapphire substrate and by removing the sapphire substrate by an etchant, namely, an etching solution. This shows that the nitrogen-based semiconductor thick film alone is left as the nitrogen-based semiconductor substrate.

In FIG. 2A, the sapphire substrate depicted by 11 is prepared which has a surface of (0001) plane, namely, c-plane and a thickness of 300 μm. On the sapphire substrate 11, a GaN buffer layer is deposited to a thickness of about 1 μm by the use of a metal organic vapor phase epitaxy (MOVPE) technique. Thereafter, SiO₂ film is formed on the GaN buffer layer and is selectively etched by a photolithography technique and wet etching to separate the SiO₂ film into masks (SiO₂ films) 13 and growth regions 14, as illustrated in FIG. 2A. The masks 13 and the growth regions 14 have widths of 4 and 3 μm, respectively, and are extended in stripe shapes. Each direction of the stripes is inclined by 10 degrees from a direction of [1 1 −2 0].

The masks 13 and the growth regions 14 serve to deposit a GaN crystal of a high quality, as will become clear as the description proceeds.

Subsequently, the masks 13 and the growth regions 14 are embedded by or covered with a GaN film 15. The GaN film 15 is deposited to a thickness of 250 μm by the use of a hydride vapor phase epitaxy (HVPE) technique of a chloride- transport method, which is carried out by using hydrogen chloride (HCl)/Ga, NH₃, and H₂. Specifically, the GaN film 15 is epitaxially grown on the conditions that a growth temperature is kept at a temperature of 1000° C. and both HCl and NH₃ gas are given on Ga at rates of 40 cc/minute and 1000 cc/minute, respectively. Thus, the masks 13 and the growth regions 14 are totally covered with the GaN film of 250 μm thick. According to this method, it has been confirmed that the GaN film is excellent in crystallinity and flatness of its surface.

As shown in FIG. 2B, a SiO₂ film 16 is deposited to a thickness of 200 nm on the surface of the GaN film 15 and a protection film 17 is formed on the SiO₂ film 16. The illustrate protection film 17 is composed of a titanium (Ti) film of 60 nm thick and a gold (Au) film of 0.4 μm thick. After deposition of the protection film 17, a heat treatment is carried out at a temperature of 450° C. for ten minutes within a hydrogen atmosphere.

Next, provision is made of a beaker with a reflux condenser and a mixed solution or an etchant obtained by mixing phosphoric acid and sulfuric acid at the ratio of 1:2. The mixed solution is entered into the beaker and is heated to a temperature of 335° C. In this event, moisture content is thoroughly removed from phosphoric acid and sulfuric acid by heating them at a temperature of 100° C. to vaporize the moisture content from them. Soaked in the vaporized mixed solution is the sapphire substrate 11 to which the GaN thin film 15, the SiO₂ film 16, and the protection film 17 are attached. Under the circumstances, the sapphire substrate 11 is etched in the mixed solution or etchant. The sapphire substrate 11 of 300 μm thick is completely dissolved within the mixed solution for 230 minutes. When such etching is continued, the GaN buffer layer 12, the masks 13 of SiO₂, and a portion of the GaN thick film 15 close to the sapphire substrate 11 are also etched, as shown in FIG. 2C. As a result, the GaN thick film 15, the SiO₂ film 16, and the protection film 17 alone are left un-etched.

Thereafter, the protection film 17 on the SiO₂ film 16 is etched by a mixed solution of nitric acid and hydrochloric acid and the SiO₂ film 16 is thereafter removed by hydrofluoric acid to leave the GaN thick film 15 alone, as shown in FIG. 2D. The GaN thick film 15 serves as a nitrogen-based semiconductor substrate.

In the example illustrated in FIGS. 2A through 2D, the GaN thick film 15 is protected by the protection film 17 while the sapphire substrate 11 is etched. Therefore, the GaN thick film 15 is never exposed to the etchant of the sapphire substrate 11. As a result, the GaN thick film 15 is kept flat in its surface and is not roughened on its surface. The GaN thick film 15 may be polished on its back surface which was contacted with the sapphire substrate 11 and which may be flattened.

According to the first embodiment mentioned above, the sapphire substrate is removed by the etchant prepared for etching the sapphire, so as to separate the nitrogen-based semiconductor thick film from the sapphire substrate. With this method, it is possible to separate the nitrogen-based semiconductor thick film without any damage that might occur on the nitrogen-based semiconductor thick film due to mechanical polishing.

Accordingly, using, as the thick film substrate, the GaN thick film 15 obtained in the above-mentioned manner enables to manufacture a nitrogen-based semiconductor structure which is excellent in characteristics.

In the above-mentioned example, the sapphire substrate 11 has the thickness of 300 μm. However, the sapphire substrate can accomplish similar effects even when it is different in thickness of the extent that no crack takes place on the GaN thick film due to thermal distortion after formation of the GaN thick film.

In addition, the c-plane of the sapphire substrate is used in the above-mentioned example but etching can be also accomplished by using a sapphire substrate which has a low-index plane, such as an M-plane (1 −1 0 0), an R-plane (1 −1 0 2), or the like. Moreover, similar effects can be attained by using a sapphire substrate which is subtly inclined from the c-plane.

Although the etching has been conducted in the above-mentioned example by the use of the mixed solution of phosphoric acid and sulfuric acid kept at the temperature of 335° C., this invention may not be restricted to the mixed solution mentioned. For example, a temperature of an etchant is preferably not lower than 300° C. even if the temperature of the etchant is changed, as understood from FIG. 3.

As the protection film 35 of the GaN thick film 35, use is made of the Ti film of 50 nm thick and the Au film of 0.5 μm thick in the example. However, the protection film 35 may be formed by a material and a thickness that withstand the mixed solution of phosphoric acid and sulfuric acid. In the illustrated example, the SiO₂ film 16 underlies the protection film Ti—Au in order to avoid metallic contamination at a portion adjacent to the surface of the GaN thick film 35. However, the SiO₂ film 16 may not be placed on the GaN thick film 35.

As a material of the protection film 35 placed over the GaN thick film 35, is used Pt, Ti—Pt—Au, Ti—Pt, Au, Pd—Au, Ni—Au, Al—Au, AuZn, AuGe, or the like, instead of Ti—Au. At any rate, the protection film 35 may be formed by the material against the etchant of phosphoric acid and sulfuric acid.

In the above-mentioned example, the GaN buffer layer 32 and the GaN thick film 35 are deposited on the sapphire substrate 31. However, they are replaced by InₓGa₁₋ₓN (0≦x≦1), AlₓGa₁₋ₓN (0≦x≦1), and AlₓIn_{y}Ga_{1-x-y}N (0≦x+y≦1) or a lamina structure of them. In this event, an impurity of an n-type or a p-type may be added to each layer or film.

[Second Embodiment]

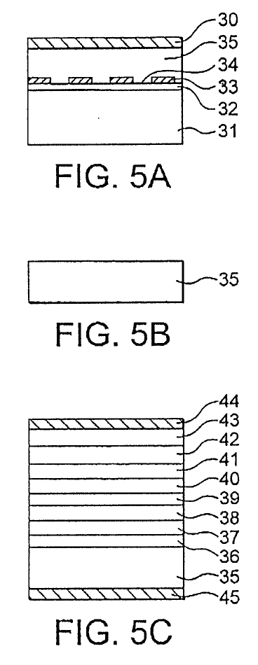

Referring to FIGS. 5A through 5C, description will be made about a method according to a second embodiment of this invention. In the second embodiment, a nitrogen-based semiconductor device is manufactured by etching out a sapphire substrate 31 from a nitrogen-based semiconductor thick film deposited on the sapphire substrate 31 by the use of an etchant to leave the nitrogen-based semiconductor thick film and by carrying out epitaxial growth by using the nitrogen-based semiconductor thick film as a substrate.

Specifically, a sapphire substrate 31 is used as a provisional substrate in the second embodiment and has a thickness of 300 μm and a surface of (0001) plane. On the sapphire substrate 31, a GaN buffer layer 32 is deposited to a thickness of about 1 μm by the MOVPE technique, as shown in FIG. 5A.

Subsequently, a SiO₂ film is formed on the GaN buffer layer 32 and is selectively etched by photolithography and wet etching and separated into masks 33 and openings 34 each of which is extended in a stripe shape in a direction depicted by [1 −1 0 0]. Thereafter, epitaxial growth of a GaN thick film 35 is carried out at a temperature of 950° C. by the use of vapor phase epitaxy (VPE) which takes a transport method of using gallium chloride as a group III raw material. In this event, the GaN thick film 35 starts growing from the openings 34 and proceeds to a lateral direction of FIGS. 5A to 5C so as to cover the masks 33. As a result, the masks 33 are embedded with the GaN thick films 35 due to lateral growth of the GaN thick film 35. Thereafter, the GaN thick film 35 is deposited to a thickness of about 250 μm. This means that the selective formation of the masks 33 on the GaN buffer film 34 is helpful to provide an excellent quality of the GaN thick film 35 because the lateral growth is promoted due to the selective formation of the masks 33 on the GaN buffer film 34.

Subsequently, a protection film 30 is formed on the surface of the epitaxial growth layer, namely, the GaN thick film 35. The illustrated protection layer 30 may be formed on a SiO₂ film (not shown) which is not thinner than 50 nm and may be composed of a Ti film of about 50 nm thick and a Au film of more than 0.1 μm thick. After deposition of the protection film 30, annealing is carried out at a temperature which is equal to or higher than 400° C. to obtain a structure illustrated in FIG. 5A.

Next, the sapphire substrate 31 is etched out by using a mixed solution of phosphoric acid and sulfuric acid as an etchant. The etching is continued to etch the GaN film 32, the SiO₂ masks 33, and a portion of the GaN thick film 35 adjacent to the masks 33. Then, the protection film 30 of Ti—Au is removed by an aqua regia of a mixed solution of concentrated hydrochloric acid and concentrated nitric acid and the SiO₂ film 33 is removed by HF (hydrofluoric acid). Thus, a crystal formed by the GaN thick film 35 (FIG. 5B) is obtained by removing the sapphire substrate.

Thereafter, a nitrogen-based semiconductor laser structure is formed by the use of the GaN thick film 35 by the MOVPE. In this event, the GaN thick film 35 is heated to a temperature of 1000° C. to deposit an n-type GaN layer 36 of 1 μm thick doped with Si, an n-type Al_{0.5}Ga_{0.85}N clad layer 37 of 0.4 μm thick doped with Si, and an n-type GaN optical guide layer 38 of 0.1 μm thick doped with Si. On the n-type GaN optical guide layer 38, is deposited an active layer 39 of a multi-quantum well structure that has a period of three and that is composed of an undoped In_{0.2}Ga_{0.8}N quantum well layer of 2.5 nm thick and an undoped In_{0.05}Ga_{0.95}N barrier layer of 5 nm thick. On the active layer 39, further successively deposited a p-type Al_{0.2}Ga_{0.8}N layer 40 of 20 nm thick doped with Mg, a p-type GaN optical guide layer 41 of 0.1 μm thick doped with Mg, a p-type Al_{0.1}Ga_{0.9}N clad layer 42 of 0.4 μm thick doped with Mg, and a p-type GaN contact layer 43 of 0.5 μm thick doped with Mg. On the p-type GaN contact layer 43, is deposited a p-type electrode 44 which is composed of Pd of 50 nm thick and Au of 0.3 μm thick. Finally, an n-type electrode 45 is deposited on a rear surface of the GaN thick film 35 and is composed of Ti of 50 nm thick and Al of 0.3 μm thick.

In the second embodiment, the crystal of the GaN thick film 35 is obtained by removing the sapphire substrate used as the provisional substrate. Furthermore, the GaN thick film 35 is used as a substrate of forming a light emitting device, such as a semiconductor laser (LD), a light emitting diode, and an electronic device, such as an MOS transistor. With this structure, excellent crytallinity can be accomplished. In addition, it is possible to solve the problems that might occur on using the sapphire substrate as the provisional substrate.

Although the c-plane of the sapphire substrate is used in the second embodiment, etching can be carried out even by using a low index substrate, such as an M-plane of (1 −1 0 0), an R-plane (1 −1 0 2) or the like. Similar effects may be achieved even by using a sapphire substrate which has a surface subtly inclined from the c-plane.

Like the first embodiment, the second embodiment may not be restricted to the above-mentioned protection film 37 and the like. Instead of Ti—Au exemplified above, Pt, Ti—Pt—Au, Ti—Pt, Au, Pd—Au, Ni—Au, Al—Au, AuZn, AuGe, or the like is used as a material of the protection film 35 placed over the GaN thick film 35. At any rate, the protection film 35 may be formed by the material against the etchant of phosphoric acid and sulfuric acid.

In the above-mentioned example, the GaN buffer layer 32 and the GaN thick film 35 are deposited on the sapphire substrate 31. However, they are replaced by InₓGa₁₋ₓN (0≦x≦1), AlₓGa₁₋ₓN (0≦x≦1), and AlₓIn_{y}Ga_{1-x-y}N (0≦x+y≦1) or a lamina structure of them. In this event, an impurity of an n-type or a p-type may be added to each layer or film.

In the illustrated example, all the sapphire substrate 31, the masks 33, and the selective growth regions 34 are etched by the same mixed solution. However, the sapphire substrate 31 alone may be etched by the mixed solution while the remaining masks 33 and the selective growth regions 34 may be removed by polishing or the like together with a portion of the GaN thick film 35. The rear surface of the nitrogen-based semiconductor layer, such as the GaN thick film 35 may be ground to be flattened after removal of the sapphire substrate 31.

[Third Embodiment]

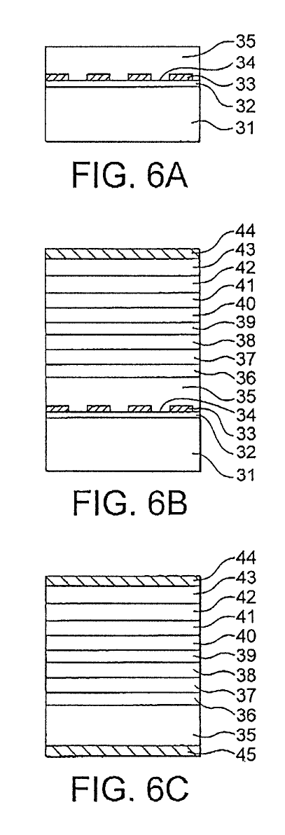

Referring to FIGS. 6A through 6C, description will be made about a method according to a third embodiment of this invention. In the third embodiment, a nitrogen-based semiconductor laser device is manufactured by successively epitaxially growing a nitrogen-based semiconductor thick film and a nitrogen-based semiconductor laser structure on a sapphire substrate and by removing the sapphire substrate by an etchant.

More specifically, a sapphire substrate 31 which has a thickness of 300 μm and a surface of (0001) plane is prepared as a provisional substrate and a GaN film 32 is deposited on the surface of the sapphire substrate 31 to a thickness of 1 μm. On the GaN film 32, is formed a silicon dioxide (SiO₂) film which is selectively etched by photolithography and wet etching technique to separate the masks 33 and the growth regions 34. The masks 33 and the growth regions 34 are shaped into stripe configurations. Each stripe is extended in the direction of [1, −1, 0,0]. Thereafter, the GaN thick film 35 is deposited to a thickness of 300 μm by the use of Vapor Phase Epitaxy (VPE) known as a chloride transport method using hydrogen chloride (HCl)/Ga, ammonia (NH3), and hydrogen (H₂), as illustrated in FIG. 6A. In the illustrated example, the GaN thick film 35 is doped as an impurity with Si and is rendered into an n-type GaN thick film. A combination of the sapphire substrate 31 and the GaN thick film 35 as shown in FIG. 6A may be referred to as a heterostructure block.

Next, a nitrogen-based semiconductor laser structure is formed on the GaN thick film 35 by the use of the MOVPE. In this event, the block illustrated in FIG. 6A is heated to a temperature of 1000° C. to successively deposit, on the GaN thick film 35, an n-type GaN layer 36 of 1 μm thick doped with Si, an n-type Al_{0.15}Ga_{0.85}N clad layer 37 of 0.4 μm thick doped with Si, and an n-type GaN optical guide layer 38 of 0.1 μm thick doped with Si. On the n-type GaN optical guide layer 38, is deposited an active layer 39 of a multi-quantum well structure that has a period of three and that is composed of an undoped In_{0.2}Ga_{0.8}N quantum well layer of 2.5 nm thick and an undoped In_{0.05}Ga_{0.95}N barrier layer of 5 nm thick. On the active layer 39, further successively deposited a p-type Al_{0.2}Ga_{0.8}N layer 40 of 20 nm thick doped with Mg, a p-type GaN optical guide layer 41 of 0.1 μm thick doped with Mg, a p-type Al_{0.1}Ga_{0.9}N clad layer 42 of 0.4 μm thick doped with Mg, and a p-type GaN contact layer 43 of 0.5 μm thick doped with Mg. On the p-type GaN contact layer 43, is deposited a p-type electrode 44 which is composed of Pd of 50 nm thick and Au of 0.3 μm thick. Furthermore, a heat treatment is performed at a temperature of 450° C. after deposition of the p-type electrode 44. Thus, the structure illustrated in FIG. 6B is obtained with the sapphire substrate 31 attached to the GaN thick film 35 and will be called a nitrogen-based semiconductor laser structure. Herein, it is to be noted that the p-type electrode 44 serves to protect the surface of the GaN film 43 on etching the sapphire substrate 31, as will become clear later.

Subsequently, the nitrogen-based semiconductor laser structure is soaked into an etchant which is mixed at a ratio of phosphoric acid (1) and sulfuric acid (2) and which is kept at a temperature of 350° C. Thus, the sapphire substrate 31 is etched out in the etchant. As shown in FIG. 4, the sapphire substrate 31 is etched at an etching rate of 150 μm/hour when the etchant is kept at the temperature of 350° C. and the sapphire substrate 31 of 300 μm thick is therefore removed for 120 minutes or so. Like in the first and the second embodiments, the GaN film 32, the masks 33, and a portion of the GaN thick film 35 are also dissolved by the etchant. In the illustrated example, the GaN thick film 35 is etched to a thickness of 50 μm from a boundary between the GaN buffer layer 32 and the GaN thick film 35 and, as a result, a rear surface of the GaN thick film 35 is exposed. Finally, an n-type electrode 45 is deposited on the rear surface of the GaN thick film 35 and is composed of Ti of 50 nm thick and Au of 0.3 μm thick. Thus, the structure illustrated in FIG. 6C is attained and is operable as a nitrogen-based semiconductor laser device.

In each nitrogen-based semiconductor laser device manufactured in accordance with the methods of the, second and the third embodiments, the GaN thick film 35 which has an M-plane of cleavage is used as the substrate. This shows that a cleavage can be caused to occur along the M-plane of the GaN thick film 35. As a result, the above-mentioned methods dispense with a complex process, such as reactive ion etching or the like, so as to form mirror surfaces. Therefore, the above-mentioned methods enable to manufacture the nitrogen-based semiconductor laser device that is excellent in flatness. In addition, the n-type electrode 45 can be formed on the rear surface of the sapphire substrate 31. This also dispenses with reactive ion etching that is conventionally conducted to deposit the electrode. At any rate, this invention can simplify the process of manufacturing the nitrogen-based semiconductor laser device.

Although the c-plane of the sapphire substrate 31 is used in the third embodiment, etching can be carried out even by using a low index substrate, such as an M-plane of (1 −1 0 0), an R-plane (1 −1 0 2) or the like. Similar effects may be achieved even by using a sapphire substrate which has a surface subtly inclined from the c-plane.

In the illustrated example, all the sapphire substrate 31, the masks 33, and the selective growth regions 34 are etched by the same mixed solution to the thickness of 50 μm from the boundary between the GaN thick film 35 and the GaN film 32. However, the sapphire substrate 31 alone may be etched by the mixed solution while the remaining masks 33 and the selective growth regions 34 may be removed by polishing, grinding, or the like together with a portion of the GaN thick film 35. In this event, the n-type electrode is thereafter formed and the mirror surfaces of a cavity are also formed due to a cleavage.

As mentioned above, this invention is advantageous in that no influence, such as cracks or so take place on the growth layers of the nitrogen-based semiconductor deposited on the substrate, because the nitrogen-based semiconductor substrate alone is left with the sapphire substrate removed.

While this invention has thus far been described in conjunction with a few embodiments thereof, it will be readily possible for those skilled in the art to put this invention into practice in various other manners. For example, the GaN buffer layer 32 may not be always deposited on the sapphire substrate. In addition, the sapphire substrate may be replaced by any other provisional substrates that may be etched by an etchant or an etching solution.

What is claimed is:

1. A method of manufacturing a nitrogen-based semiconductor layer, comprising the steps of:
growing the nitrogen-based semiconductor layer on a provisional substrate which forms a heterojunction with the nitrogen-based semiconductor layer; and
etching out the provisional substrate by the use of an etchant for the provisional substrate to leave only the nitrogen-based semiconductor layer as a nitrogen-based semiconductor substrate.

2. A method as claimed in claim 1, further comprising, before the etching step, the step of:
covering the nitrogen-based semiconductor layer with a protection layer against the etchant;
the etching step being carried out with the nitrogen-based semiconductor layer covered with the protection layer to etch out the provisional substrate and to thereby leave the nitrogen-based semiconductor layer and the protection layer.

3. A method as claimed in claim 1, wherein the nitrogen-based semiconductor layer is formed by a nitrogen-based semiconductor thick film.

4. A method as claimed in claim 1, wherein the nitrogen-based semiconductor layer implements a nitrogen-based semiconductor device structure.

5. A method as claimed in claim 1, further comprising the step of:
processing the nitrogen-based semiconductor substrate into a nitrogen-based semiconductor device after the provisional substrate is etched out.

6. A method as claimed in claim 2, further comprising the step of:
processing the nitrogen-based semiconductor substrate into a nitrogen-based semiconductor device after the provisional substrate is etched out.

7. A method as claimed in claim 6, wherein the nitrogen-based semiconductor device has an electrode formed by the protection layer.

8. A method as claimed in claim 1, wherein the provisional substrate is a sapphire substrate while the etchant is formed by a mixed solution of phosphoric acid and sulfuric acid or another mixed solution including the phosphoric acid and the sulfuric acid.

9. A method as claimed in claim 2, wherein the protection layer is formed by at least one material selected from a group consisting of Au, Pt, Ti—Au, Pd—Au, Ni—Au, Ti—Pt—Au, AuZn, and AuGe.

10. A method as claimed in claim 1, wherein the nitrogen-based semiconductor layer includes either InₓGa₁₋ₓN (0≦x≦1) or AlₓGa₁₋ₓN (0≦x≦1).

11. A method as claimed in claim 1, wherein the nitrogen-based semiconductor layer includes at least two components selected from a group consisting of InₓGa₁₋ₓN (0≦x≦1), AlₓGa₁₋ₓN (0≦x≦1), and AlₓInyGa_{1-x-y}N (0≦x+y≦1).

12. A method as claimed in claim 8, wherein the sapphire is etched out by the use of the etchant kept at a temperature not lower than 300° C.

13. A method as claimed in claim 4, wherein the nitrogen-based semiconductor device structure forms a semiconductor laser, a light emitting diode, and/or a field effect transistor.

14. A method as claimed in claim 1, further comprising the step of:
polishing the nitrogen-based semiconductor layer on its surface faced to the provisional substrate so as to flatten the surface.
